(19) United States
(12) Patent Application Publication
(10) Pub. No.: US 2023/0137958 A1
(43) Pub. Date: May 4, 2023

(54) Integrated Circuitry, Memory Circuitry Comprising Strings Of Memory Cells, And Method Of Forming Integrated Circuitry

(71) Applicant: Micron Technology, Inc., Boise, ID (US)

(72) Inventors: Shuangqiang Luo, Boise, ID (US); Nancy M. Lomeli, Boise, ID (US); Rui Zhang, Boise, ID (US)

(73) Assignee: Micron Technology, Inc., Boise, ID (US)

(21) Appl. No.: 17/517,355

(22) Filed: Nov. 2, 2021

(51) Int. Cl. H01L 23/528; H01L 27/11519; H01L 27/11524; H01L 27/11556; H01L 27/11565; H01L 27/1157; H01L 27/11582; H01L 23/522; H01L 21/768

(52) U.S. Cl. CPC H01L 23/528; H01L 27/11519; H01L 27/11524; H01L 27/11556; H01L 27/11565; H01L 27/1157; H01L 27/11582; H01L 23/5226; H01L 21/76816; G11C 16/0483

(57) ABSTRACT

Memory circuitry comprising strings of memory cells comprising laterally-spaced memory blocks individually comprise a vertical stack comprising alternating insulative tiers and conductive tiers. Channel-material strings of memory cells extend through the insulative tiers and the conductive tiers in a memory-array region. The insulative tiers and the conductive tiers of the laterally-spaced memory blocks extend from the memory-array region into a stair-step region. Individual stairs in the stair-step region comprise one of the conductive tiers and a riser. Conductive vias are individually directly against conductive material that is in the one conductive tier in one of the individual stairs. Individual of the conductive vias where directly against the conductive material are horizontally-longitudinally-elongated at an angle of 0° to 60° horizontally from the riser of the one individual stair. Other embodiments, including method, are disclosed.

### TECHNICAL FIELD

Embodiments disclosed herein pertain to integrated circuitry, to memory circuitry comprising strings of memory cells, and to methods of forming integrated circuitry.

### BACKGROUND

Memory is one type of integrated circuitry and is used in computer systems for storing data. Memory may be fabricated in one or more arrays of individual memory cells. Memory cells may be written to, or read from, using digitlines (which may also be referred to as bitlines, data lines, or sense lines) and access lines (which may also be referred to as wordlines). The sense lines may conductively interconnect memory cells along columns of the array, and the access lines may conductively interconnect memory cells along rows of the array. Each memory cell may be uniquely addressed through the combination of a sense line and an access line.

Memory cells may be volatile, semi-volatile, or non-volatile. Non-volatile memory cells can store data for extended periods of time in the absence of power. Non-volatile memory is conventionally specified to be memory having a retention time of at least about 10 years. Volatile memory dissipates and is therefore refreshed/rewritten to maintain data storage. Volatile memory may have a retention time of milliseconds or less. Regardless, memory cells are configured to retain or store memory in at least two different selectable states. In a binary system, the states are considered as either a “0” or a “1”. In other systems, at least some individual memory cells may be configured to store more than two levels or states of information.

A field effect transistor is one type of electronic component that may be used in a memory cell. These transistors comprise a pair of conductive source/drain regions having a semiconductive channel region there-between. A conductive gate is adjacent the channel region and separated there-from by a thin gate insulator. Application of a suitable voltage to the gate allows current to flow from one of the source/drain regions to the other through the channel region. When the voltage is removed from the gate, current is largely prevented from flowing through the channel region. Field effect transistors may also include additional structure, for example a reversibly programmable charge-storage region as part of the gate construction between the gate insulator and the conductive gate.

Flash memory is one type of memory and has numerous uses in modern computers and devices. For instance, modern personal computers may have BIOS stored on a flash memory chip. As another example, it is becoming increasingly common for computers and other devices to utilize flash memory in solid state drives to replace conventional hard drives. As yet another example, flash memory is popular in wireless electronic devices because it enables manufacturers to support new communication protocols as they become standardized, and to provide the ability to remotely upgrade the devices for enhanced features.

NAND may be a basic architecture of integrated flash memory. A NAND cell unit comprises at least one selecting device coupled in series to a serial combination of memory cells (with the serial combination commonly being referred to as a NAND string). NAND architecture may be configured in a three-dimensional arrangement comprising vertically-stacked memory cells individually comprising a reversibly programmable vertical transistor. Control or other circuitry may be formed below the vertically-stacked memory cells. Other volatile or non-volatile memory array architectures may also comprise vertically-stacked memory cells that individually comprise a transistor.

Memory arrays may be arranged in memory pages, memory blocks and partial blocks (e.g., sub-blocks), and memory planes, for example as shown and described in any of U.S. Patent Application Publication Nos. 2015/0228651, 2016/0267984, and 2017/0140833. The memory blocks may at least in part define longitudinal outlines of individual wordlines in individual wordline tiers of vertically-stacked memory cells. Connections to these wordlines may occur in a so-called “stair-step structure” at an end or edge of an array of the vertically-stacked memory cells. The stair-step structure includes individual “stairs” (alternately termed “steps” or “stair-steps”) that define contact regions of the individual wordlines upon which elevationally-extending conductive vias contact to provide electrical access to the wordlines.

### BRIEF DESCRIPTION OF THE DRAWINGS

FIG. 1 is a diagrammatic view of a portion of memory circuitry comprising strings of memory cells in accordance with an embodiment of the invention.

FIGS. 2-16 are diagrammatic sectional, expanded, enlarged, and/or partial views of the construction of FIG. 1 or portions thereof, and/or of alternate embodiments thereof.

FIGS. 17-20 show example method embodiments of the invention.

### DETAILED DESCRIPTION OF EXAMPLE EMBODIMENTS

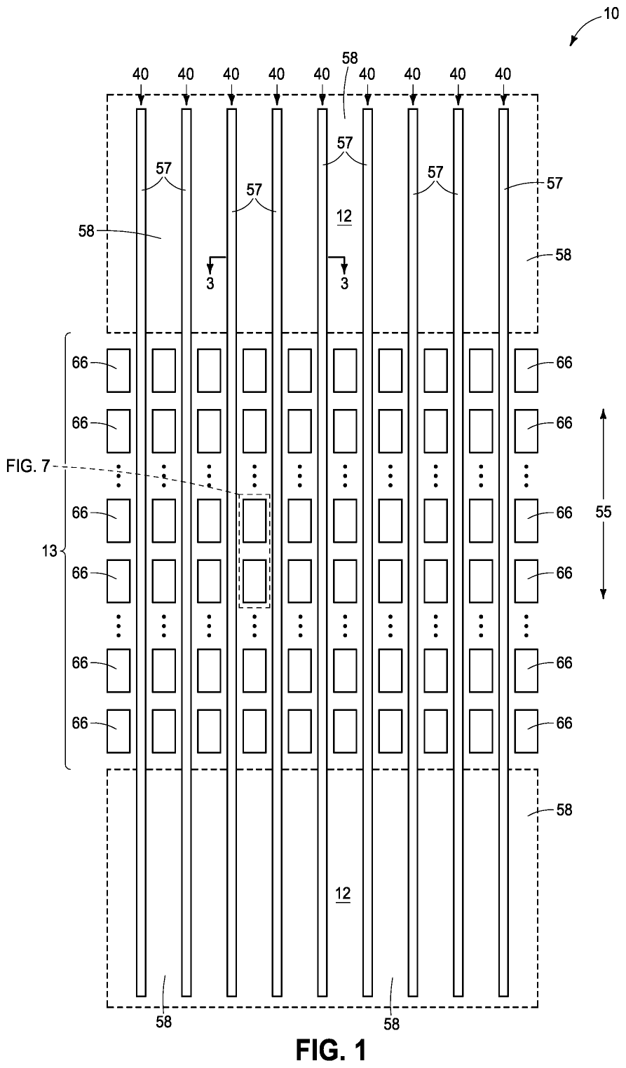

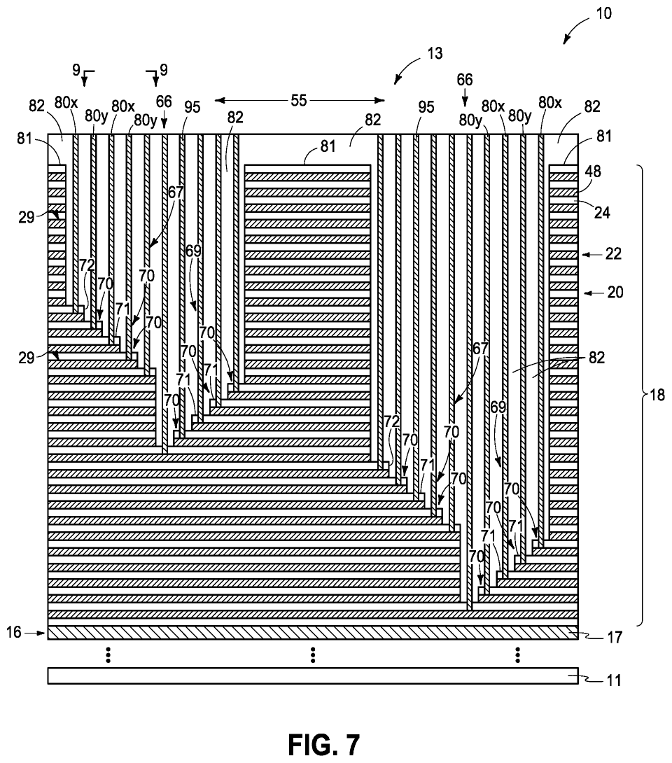

FIGS. 1-10 show a construction 10 having two memory-array regions 12 comprising elevationally-extending strings 49 of transistors and/or memory cells 56 (e.g., comprising NAND). A stair-step region 13 is between memory-array regions 12. Construction 10 may comprise only a single memory-array region 12 or may comprise more than two memory-array regions 12 (neither being shown). FIGS. 7-10 are of different and varying scales compared to FIGS. 1-6 for clarity in disclosure more pertinent to components in stair-step region 13 than in memory-array regions 12. Construction 10 comprises a base substrate 11 having any one or more of conductive/conductor/conducting, semiconductive/semiconductor/semiconducting, or insulative/insulator/insulating (i.e., electrically herein) materials. Various materials have been formed elevationally over base substrate 11. Materials may be aside, elevationally inward, or elevationally outward of the FIGS. 1-10-depicted materials. For example, other partially or wholly fabricated components of integrated circuitry may be provided somewhere above, about, or within base substrate 11. Control and/or other peripheral circuitry for operating components within an array (e.g., individual array regions 12) of elevationally-extending strings of memory cells may also be fabricated and may or may not be wholly or partially within an array or sub-array. Further, multiple sub-arrays may also be fabricated and operated independently, in tandem, or otherwise relative one another. In this document, a “sub-array” may also be considered as an array.

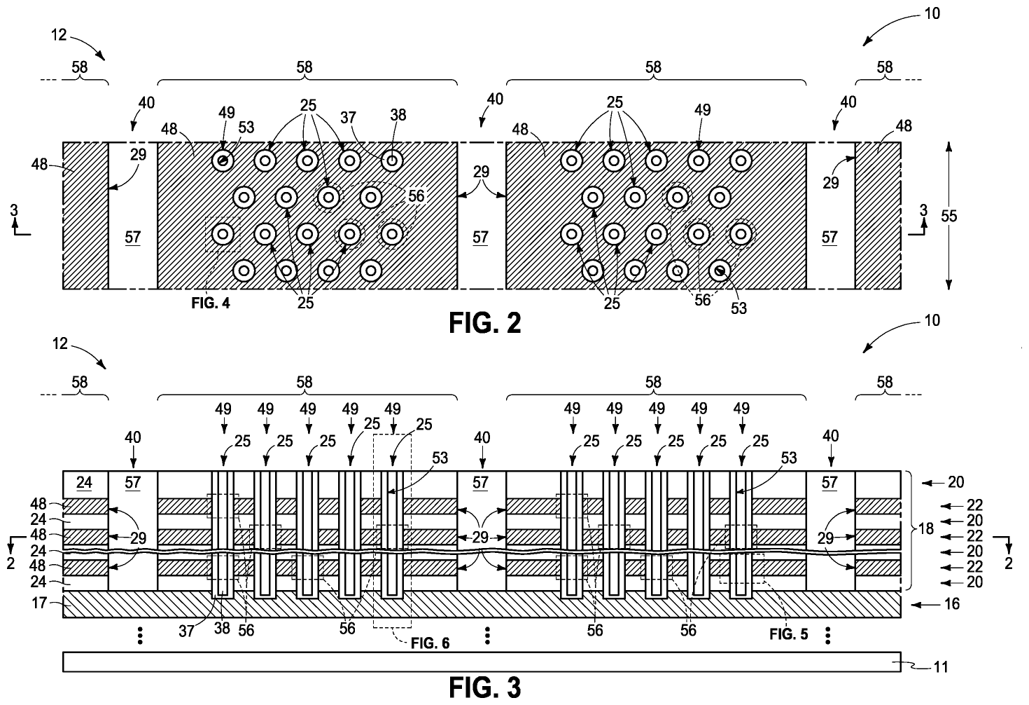

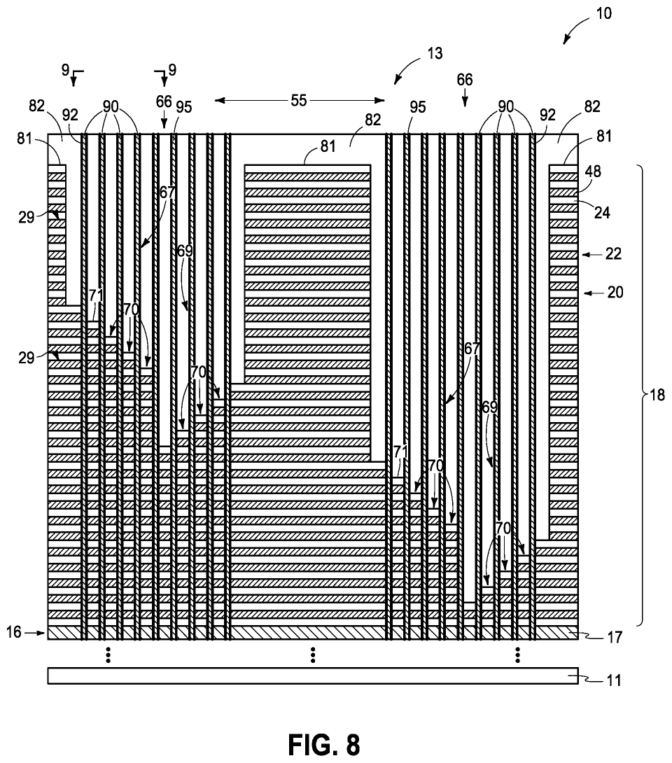

A conductor tier 16 comprising conductor material 17 is above substrate 11. Conductor tier 16 may comprise part of control circuitry (e.g., peripheral-under-array circuitry and/or a common source line or plate) used to control read and write access to the transistors and/or memory cells that will be formed within array 12. A vertical stack 18 comprising vertically-alternating insulative tiers 20 and conductive tiers 22 is above conductor tier 16. In some embodiments, conductive tiers 22 may be referred to as first tiers 22 and insulative tiers 20 are referred to as second tiers 20. Insulative tiers 20 and conductive tiers 22 extend from memory-array region 12 into stair-step region 13. Example thickness for each of tiers 20 and 22 is 22 to 60 nanometers. The example uppermost tier 20 may be thicker/thickest compared to one or more other tiers 20 and/or 22. Only a small number of tiers 20 and 22 is shown in FIGS. 2-10 (more shown in FIGS. 7 and 8 as compared to FIGS. 1-6 due to scale and for clarity in stair-step region 13), with more likely stack 18 comprising dozens, a hundred or more, etc. of tiers 20 and 22. Other circuitry that may or may not be part of peripheral and/or control circuitry may be between conductor tier 16 and stack 18. For example, multiple vertically-alternating tiers of conductive material and insulative material of such circuitry may be below a lowest of the conductive tiers 22 and/or above an uppermost of the conductive tiers 22. For example, one or more select gate tiers (not shown) may be between conductor tier 16 and the lowest conductive tier 22 and one or more select gate tiers may be above an uppermost of conductive tiers 22 (not shown). Alternately or additionally, at least one of the depicted uppermost and lowest conductive tiers 22 may be a select gate tier. Example insulative tiers 20 comprise insulative material 24 (e.g., silicon dioxide and/or other material that may be of one or more composition(s)).

Channel openings 25 have been formed (e.g., by etching) through insulative tiers 20 and conductive tiers 22 to conductor tier 16. Channel openings 25 may taper radially-inward (not shown) moving deeper in stack 18. In some embodiments, channel openings 25 may go into conductor material 17 of conductor tier 16 as shown or may stop there-atop (not shown). Alternately, as an example, channel openings 25 may stop atop or within the lowest insulative tier 20. A reason for extending channel openings 25 at least to conductor material 17 of conductor tier 16 is to assure direct electrical coupling of channel material to conductor tier 16 without using alternative processing and structure to do so when such a connection is desired. Etch-stop material (not shown) may be within or atop conductor material 17 of conductor tier 16 to facilitate stopping of the etching of channel openings 25 relative to conductor tier 16 when such is desired. Such etch-stop material may be sacrificial or non-sacrificial. By way of example and for brevity only, channel openings 25 are shown as being arranged in groups or columns of staggered rows of four and five openings 25 per row and being arrayed in laterally-spaced memory blocks 58. In this document, “block” is generic to include “sub-block”. Memory blocks 58 may be considered as being longitudinally elongated and oriented, for example along a first direction 55. Any alternate existing or future-developed arrangement and construction may be used.

The two memory-array regions 12 may be of the same or different constructions relative one another. Regardless, channel-material strings (e.g., 53) of memory cells (e.g., 56) extend through the insulative tiers (e.g., 20) and the conductive tiers (e.g., 22) in memory blocks (e.g., 58) in each of two memory-array regions 12.

Example memory blocks 58 are shown as at least in part having been defined by horizontally-elongated trenches 40 that were formed (e.g., by anisotropic etching) into stack 18. Trenches 40 will typically be wider than lower channel openings 25 (e.g., 3 to 10 times wider). Trenches 40 may have respective bottoms that are directly against conductor material 17 (e.g., atop or within) of conductor tier 16 (as shown) or may have respective bottoms that are above conductor material 17 of conductor tier 16 (not shown). Walls 57 are individually in trenches 40 between immediately-adjacent memory blocks 58. Walls 57 may provide lateral electrical isolation (insulation) between immediately-laterally-adjacent memory blocks. Walls 57 may include one or more of insulative, semiconductive, and conducting materials and, regardless, may facilitate conductive tiers 22 from shorting relative one another in a finished circuitry construction. Example insulative materials are one or more of SiO₂, Si₃N₄, Al₂O₃, and undoped polysilicon. Walls 57 may include through-array-vias (TAVs, and not shown).

Transistor channel material may be formed in the individual channel openings elevationally along the insulative tiers and the conductive tiers, thus comprising individual channel-material strings, which is directly electrically coupled with conductive material in the conductor tier. Individual memory cells of the example memory array being formed may comprise a gate region (e.g., a control-gate region) and a memory structure laterally between the gate region and the channel material. In one such embodiment, the memory structure is formed to comprise a charge-blocking region, storage material (e.g., charge-storage material), and an insulative charge-passage material. The storage material (e.g., floating gate material such as doped or undoped silicon or charge-trapping material such as silicon nitride, metal dots, etc.) of the individual memory cells is elevationally along individual of the charge-blocking regions. The insulative charge-passage material (e.g., a band gap-engineered structure having nitrogen-containing material [e.g., silicon nitride] sandwiched between two insulator oxides [e.g., silicon dioxide]) is laterally between the channel material and the storage material.

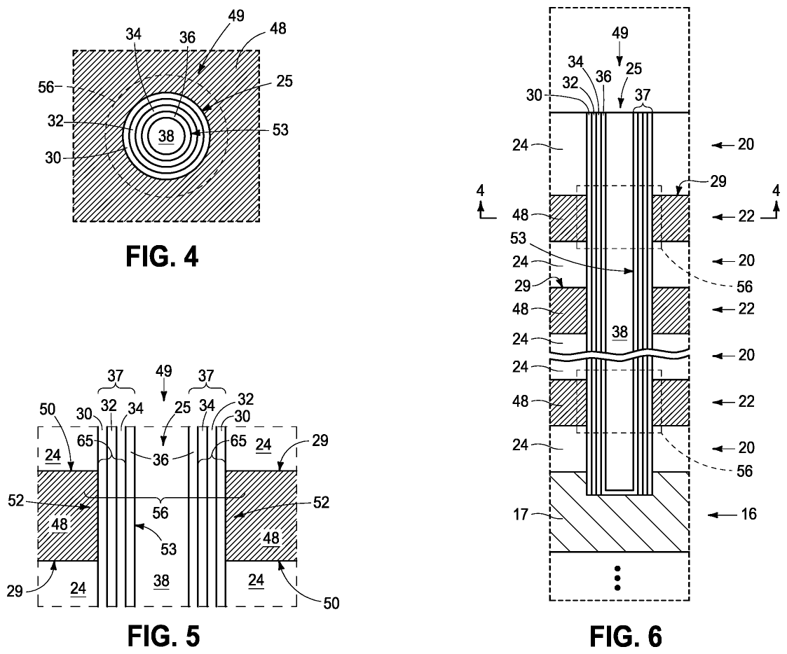

FIGS. 4-6 show one embodiment wherein charge-blocking material 30, storage material 32, and charge-passage material 34 have been formed in individual channel openings 25 elevationally along insulative tiers 20 and conductive tiers 22. Transistor materials 30, 32, and 34 (e.g., memory-cell materials) may be formed by, for example, deposition of respective thin layers thereof over stack 18 and within individual channel openings 25 followed by planarizing such back at least to a top surface of stack 18 as shown.

Channel material 36 has also been formed in channel openings 25 elevationally along insulative tiers 20 and conductive tiers 22 and comprise individual operative channel-material strings 53 in one embodiment having memory-cell materials (e.g., 30, 32, and 34) there-along and with material 24 in insulative tiers 20 being horizontally-between immediately-adjacent channel-material strings 53. Materials 30, 32, 34, and 36 are collectively shown as and only designated as material 37 in some figures due to scale. Example channel materials 36 include appropriately-doped crystalline semiconductor material, such as one or more silicon, germanium, and so-called III/V semiconductor materials (e.g., GaAs, InP, GaP, and GaN). Example thickness for each of materials 30, 32, 34, and 36 is 25 to 100 Angstroms. Punch etching may be conducted as shown to remove materials 30, 32, and 34 from the bases of channel openings 25 to expose conductor tier 16 such that channel material 36 is directly against conductor material 17 of conductor tier 16. Such punch etching may occur separately with respect to each of materials 30, 32, and 34 (as shown) or may occur collectively with respect to all after deposition of material 34 (not shown). Alternately, and by way of example only, no punch etching may be conducted and channel material 36 may be directly electrically coupled to conductor material 17 of conductor tier 16 by a separate conductive interconnect (not shown). Channel openings 25 are shown as comprising a radially-central solid dielectric material 38 (e.g., spin-on-dielectric, silicon dioxide, and/or silicon nitride). Alternately, and by way of example only, the radially-central portion within channel openings 25 may include void space(s) (not shown) and/or be devoid of solid material (not shown).

Example conductive tiers 22 comprise conducting material 48 that is part of individual conductive lines 29 (e.g., wordlines) that may extend across stair-step region 13 along first direction 55 into and within individual memory blocks 58 in each of two memory-array regions 12. Conductive lines 29 comprise part of elevationally-extending strings 49 of individual transistors and/or memory cells 56. A thin insulative liner (e.g., Al₂O₃ and not shown) may be formed before forming conducting material 48. Approximate locations of some transistors and/or some memory cells 56 are indicated with a bracket or with dashed outlines, with transistors and/or memory cells 56 being essentially ring-like or annular in the depicted example. Alternately, transistors and/or memory cells 56 may not be completely encircling relative to individual channel openings 25 such that each channel opening 25 may have two or more elevationally-extending strings 49 (e.g., multiple transistors and/or memory cells about individual channel openings in individual conductive tiers with perhaps multiple wordlines per channel opening in individual conductive tiers, and not shown). Conducting material 48 may be considered as having terminal ends 50 corresponding to control-gate regions 52 of individual transistors and/or memory cells 56. Control-gate regions 52 in the depicted embodiment comprise individual portions of individual conductive lines 29. Materials 30, 32, and 34 may be considered as a memory structure 65 that is laterally between control-gate region 52 and channel material 36.

A charge-blocking region (e.g., charge-blocking material 30) is between storage material 32 and individual control-gate regions 52. A charge block may have the following functions in a memory cell: In a program mode, the charge block may prevent charge carriers from passing out of the storage material (e.g., floating-gate material, charge-trapping material, etc.) toward the control gate, and in an erase mode the charge block may prevent charge carriers from flowing into the storage material from the control gate. Accordingly, a charge block may function to block charge migration between the control-gate region and the storage material of individual memory cells. An example charge-blocking region as shown comprises insulator material 30. By way of further examples, a charge-blocking region may comprise a laterally (e.g., radially) outer portion of the storage material (e.g., material 32) where such storage material is insulative (e.g., in the absence of any different-composition material between an insulative storage material 32 and conducting material 48). Regardless, as an additional example, an interface of a storage material and conductive material of a control gate may be sufficient to function as a charge-blocking region in the absence of any separate-composition-insulator material 30. Further, an interface of conducting material 48 with material 30 (when present) in combination with insulator material 30 may together function as a charge-blocking region, and as alternately or additionally may a laterally-outer region of an insulative storage material (e.g., a silicon nitride material 32). An example material 30 is one or more of silicon hafnium oxide and silicon dioxide.

Example stair-step region 13 comprises stair-step structures 66 that are laterally between immediately-adjacent walls 57 and have stairs 70. Example stairs 70 are arranged in two opposing flights 67, 69 and individually comprise a tread 71, a riser 72, one of insulative tiers 20 (i.e., at least one), and one of conductive tiers 22 (i.e., at least one). Individual stairs 70 are shown as having a top region that is one of insulative tiers 20 and a bottom region that is one of conductive tiers 22, although this may be reversed (not shown). Flights 67 and 69 may have the same or different number of stairs (different being shown). Only a single flight of stairs may be used (not shown) and if multiple flights are used, one of such may be dummy (i.e., a circuit-inoperative structure; e.g., flight 69 as shown). A crest 81 is between immediately-adjacent stair-step structures 66. Vertical stack 18 comprises insulator material 82 in stair-step region 13 that is directly above stairs 70 (e.g., a combination of a silicon nitride liner directly against stairs 70, with silicon dioxide thereover).

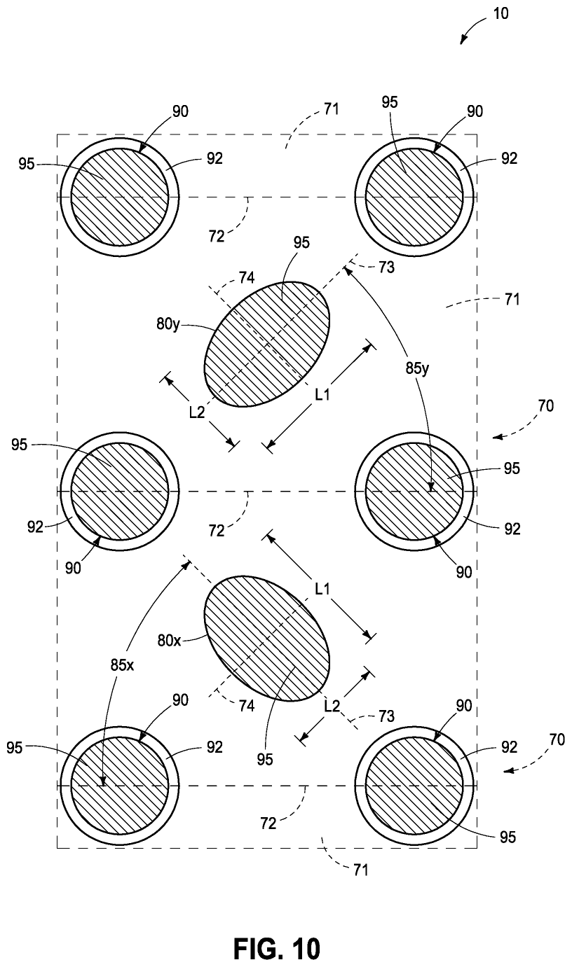

Conductive vias 80* extend through insulator material 82 (an * being used as a suffix to be inclusive of all such same-numerically-designated components that may or may not have other suffixes) and are individually directly against conducting material 48 (e.g., of a conductive line 29) that is in one conductive tier 22 in one of individual stairs 70. Example conductive vias 80* comprise conductive material 95 (e.g., metal material). Individual conductive vias 80* where directly against conducting material 48 (e.g., at top surfaces of conducting material 48) are horizontally-longitudinally-elongated at an angle 85* (FIG. 10) of 0° to 60° horizontally from riser 72 of the/its one individual stair 78. Example conductive vias 80* are shown as contacting top surfaces of conducting material 48 and may alternately or additional go downwardly into conducting material 48 (not shown). In one embodiment and as shown, angle 85* is greater than 0°, in one such embodiment is no more than 45°, in one such embodiment is no more than 30°, in one such embodiment is no more than 25°, in one such embodiment is no more than 15°, and in one such embodiment is no more than 10°. In one embodiment, the angle is 0° and thereby the individual conductive vias are elongated parallel the riser of the/its one individual stair 70 where directly against conducting material 48.

Any other attribute(s) or aspect(s) as shown and/or described herein with respect to other embodiments may be used in the embodiments shown and described with reference to the above embodiments and any of the embodiments herein may combine attributes thereof.

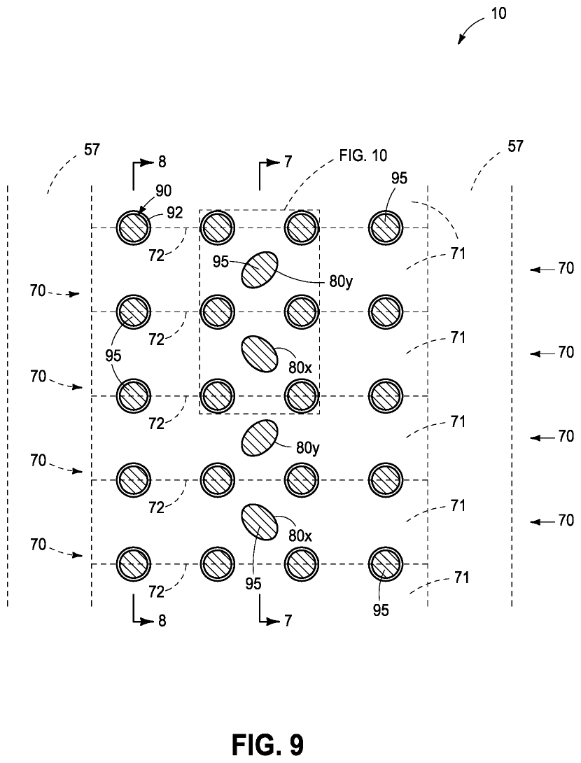

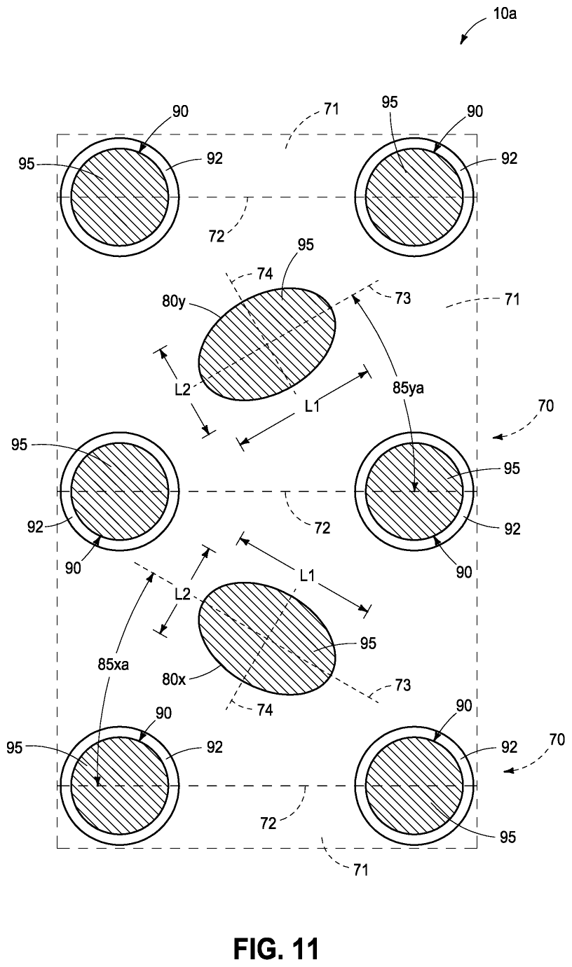

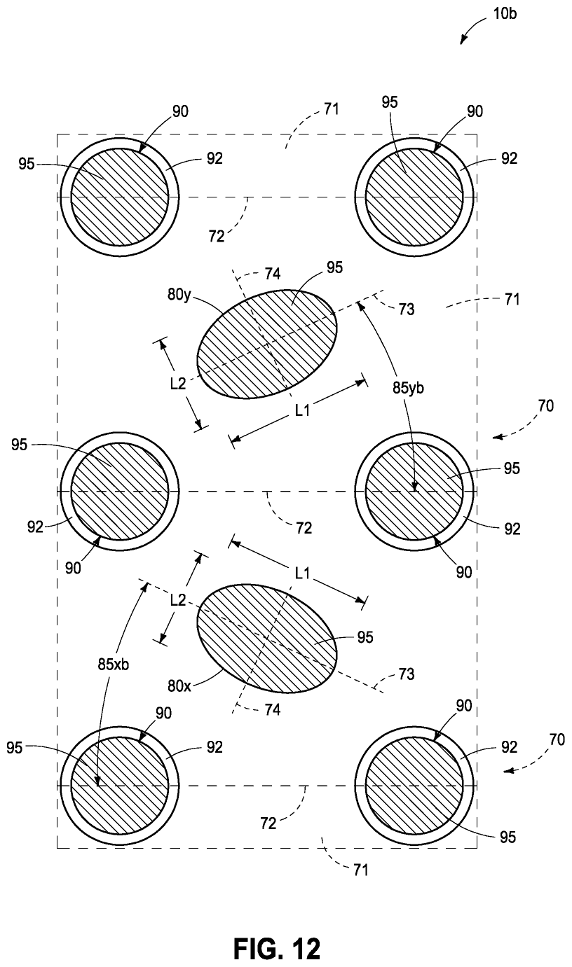

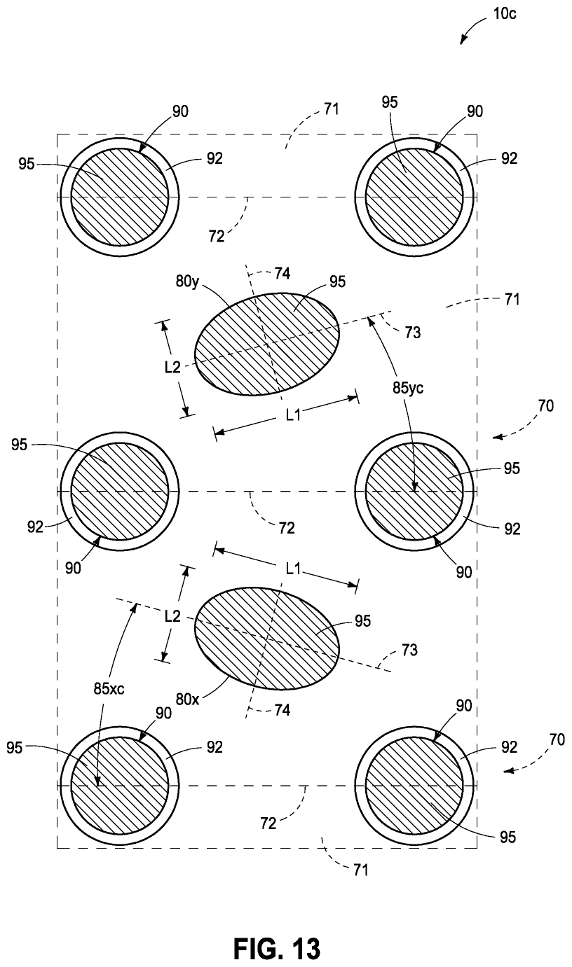

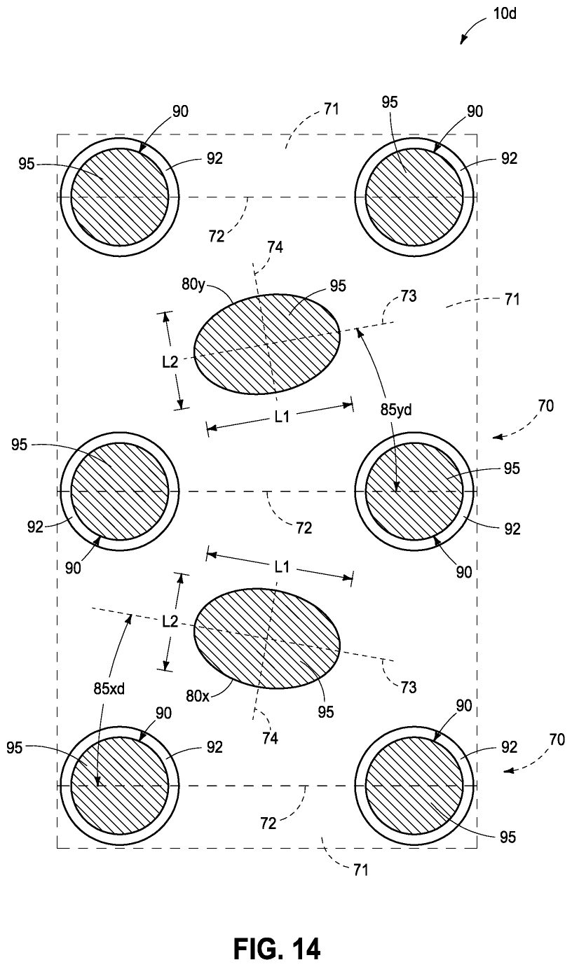

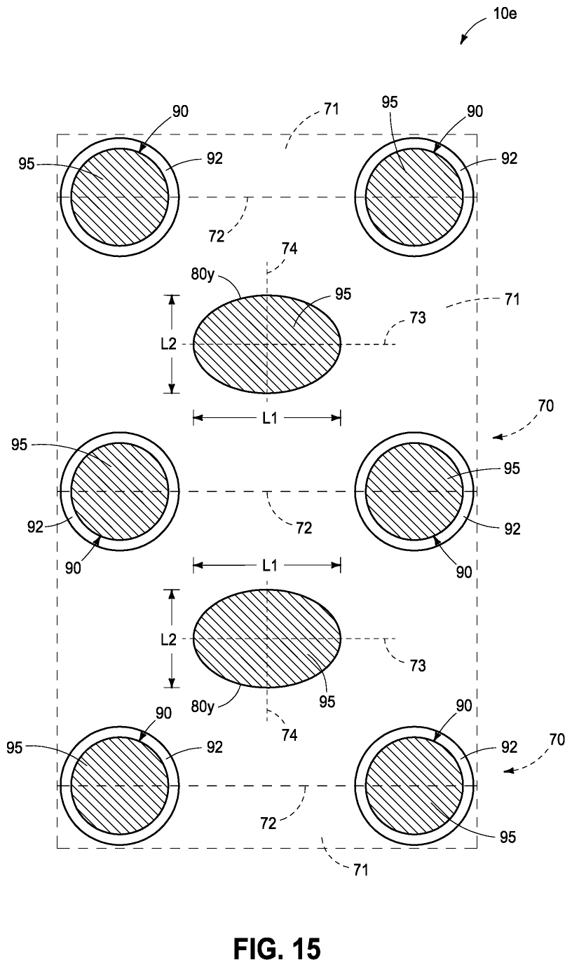

FIGS. 9 and 10 show an embodiment, where angle 85 is 45°. FIGS. 11, 12, 13, 14, and 15 show alternate embodiment constructions 10a, 10b, 10c, 10d, and 10e, respectively, having conductive vias 80* where angles 85xa, 85ya, 85xb, 85yb, 85xc, 85yc, 85xd, and 85yd are 30°, 25°, 15°, and 10°. Like numerals from the above-described embodiments have been used where appropriate, with some construction differences being indicated with the suffix “a”, “b”, “c”, “d”, or “e” or with different numerals. In FIG. 15, example axis 73 (referred to below) is parallel step riser 72, with the angle being 0° and thereby no angle being shown. Any other attribute(s) or aspect(s) as shown and/or described herein with respect to other embodiments may be used.

In one embodiment, individual conductive vias 80* are horizontally-longitudinally-elongated along a maximum-length major axis 73 (i.e., the horizontal axis that is along the longest horizontal length in the horizontal cross-section) where directly against conducting material 48. Individual conductive vias 80* have a maximum-length minor axis 74 orthogonal to maximum-length major axis 73 where directly against conducting material 48 (i.e., the horizontal axis that is along the longest horizontal width orthogonal to axis 73). Length L1 of maximum-length major axis 73 is at least 105% of length L2 of maximum-length minor axis 74 (150% being shown), in one such embodiment is no more than 175% of the length of the maximum-length minor axis, and in one such embodiment with length L 1 being 110% to 120% of length L2. In one embodiment, maximum-length minor axis L2 bisects maximum-length major axis L1. In one embodiment, maximum-length major axis L1 bisects maximum-length minor axis L2.

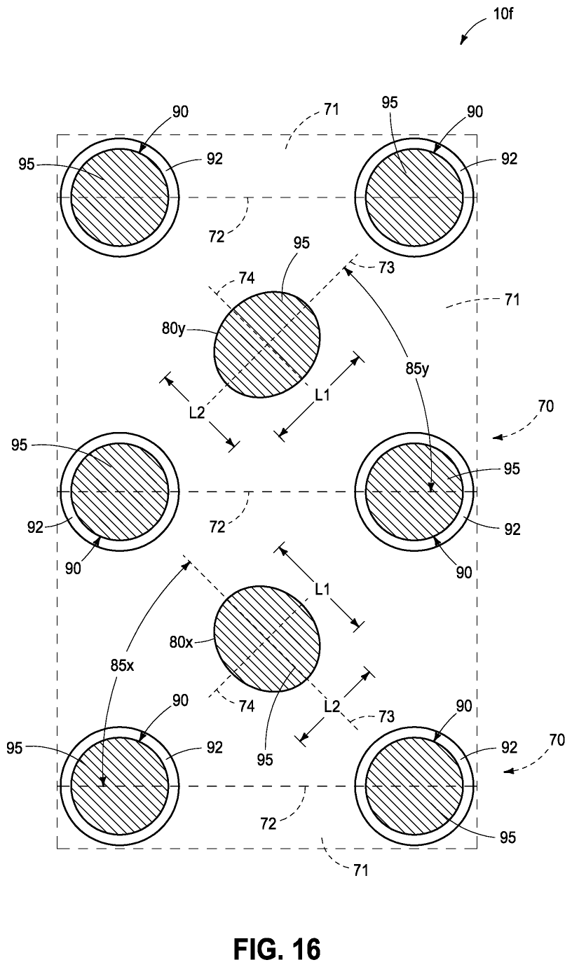

FIG. 16 shows an example alternate embodiment construction 10f where length L1 of maximum-length major axis 73 is 115% of length L2 of the maximum-length minor axis 74. Like numerals from the above-described embodiments have been used where appropriate, with some construction differences being indicated with the suffix “f” or with different numerals. Any other attribute(s) or aspect(s) as shown and/or described herein with respect to other embodiments may be used.

In one embodiment, angle 85* is greater than 0° horizontally-clockwise from riser 72 of the/its one individual stair 70 (e.g., angle 85x* of conductive vias 80x). In one embodiment, angle 85* is greater than 0° horizontally-counterclockwise from riser 72 of the/its one individual stair 70 (e.g., angle 85y* of conductive vias 80y). In one embodiment, for some of the individual conductive vias, the angle is greater than 0° horizontally-clockwise from riser 72 of the/its one individual stair 70 (e.g., conductive vias 80x and angles 85x*) and for another some of the individual conductive vias the angle is greater than 0° horizontally-counterclockwise from riser 72 of the/its one individual stair 70 (e.g., conductive vias 80y and angles 85y*).

The figures for the above example embodiments show angles 85* in each respective embodiment as being the same for all conductive vias 80*, although such is not required. For example, conductive vias 80* could collectively have multiple different random angles (not shown) and/or the clockwise and counterclockwise angles (when present) may not be equal relative one another (not shown). Further, some conductive vias may have some angles 85* that are horizontally-longitudinally-elongated at an angle greater than 60° horizontally from the riser of the one individual stair as long as the construction has at least some conductive vias that are horizontally-longitudinally-elongated at an angle of 0° to 60° horizontally from the riser of the one individual stair.

In one embodiment, the memory circuitry comprises TAVs 90 individually extending through individual of individual stairs 70. In one such embodiment and as shown, multiple TAVs 90 extend through individual risers 72 and through treads 71 of immediately-adjacent stairs 70. Example TAVs 90 have an example insulative lining 92 (e.g., silicon dioxide and/or silicon nitride) radially there-about (shown as a solid dark line in FIG. 8 due to scale). Conductive vias 80* may be routed horizontally (not shown) above stack 18 and connect (not shown) with individual TAVs 90 that extend through stack 18 to circuitry there-below. Such horizontal routing may be through TAVs extending through walls 57 and/or adjacent stair-step region 13 (neither being shown). Example TAVs 90 are shown extending through conductor tier 16. Alternately, such may stop atop or within conductor tier 16. Regardless, conductor tier 16 may be vertically-segmented in the FIGS. 7 and 8 cross-sections (not shown) as opposed to being horizontally-continuous as shown.

Some of conductive vias 80* and/or TAVs 90 may be dummy.

Embodiments of the invention encompass integrated circuitry regardless of whether comprising memory circuitry and if comprising memory circuitry regardless of whether comprising strings of memory cells. Integrated circuitry in accordance with some embodiments of the invention comprises a three-dimensional (3D) array region (e.g., 12) individually comprising tiers (e.g., 22) of electronic components (e.g., 56). The 3D array region comprises a vertical stack (e.g., 18) comprising alternating insulative tiers (e.g., 20) and conductive tiers (e.g., 22). The insulative tiers and the conductive tiers extend from the 3D array region into a stair-step region (e.g., 13). Individual stairs (e.g., 70) in the stair-step region comprise one of the conductive tiers (i.e., at least one) and a riser (e.g., 72). The integrated circuitry comprises conductive vias (e.g., 80*) that are individually directly against conducting material (e.g., 48) that is in the one conductive tier in one of the individual stairs. Individual of the conductive vias where directly against the conductive material are horizontally-longitudinally-elongated at an angle (e.g., 85*) of 0° to 60° horizontally from the riser of the one individual stair. Any other attribute(s) or aspect(s) as shown and/or described herein with respect to other embodiments may be used.

Embodiments of the invention encompass methods of forming integrated circuitry. Embodiments of the invention encompass integrated circuitry independent of method of manufacture. Nevertheless, such integrated circuitry may have any of the attributes as described herein in method embodiments. Likewise, the described method embodiments may incorporate, form, and/or have any of the attributes described with respect to structure embodiments.

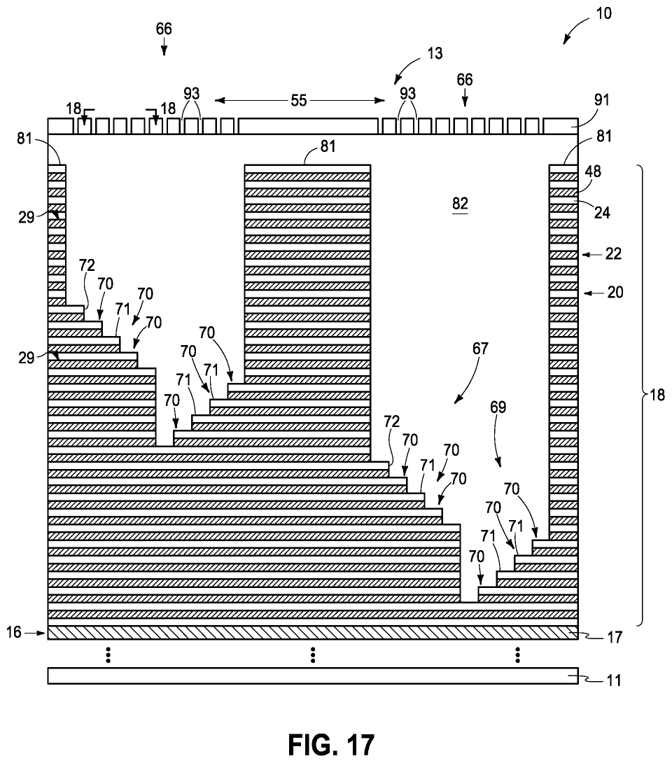

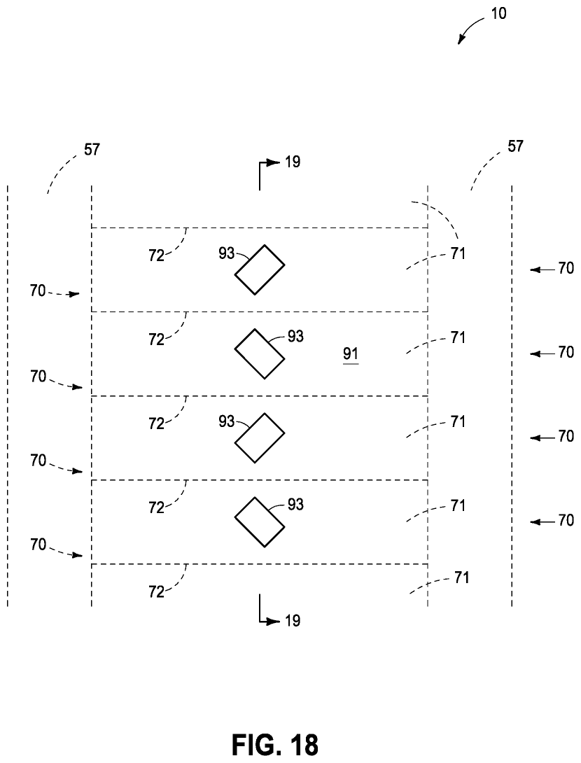

An example method embodiment of forming integrated circuity is next described with respect to FIGS. 7, 9, 10 and 17-20. Referring first to FIGS. 17 and 18, such show an example predecessor construction to that shown by FIGS. 7 and 9, respectively. A vertical stack (e.g., 18) has been formed and that comprises alternating insulative tiers (e.g., 20) and conductive tiers (e.g., 22) that will individually comprise tiers of electronic components (e.g., 56) in a three-dimensional (3D) array region (e.g., 12) in a finished-circuitry construction. The insulative tiers and the conductive tiers extend from the 3D array region into a stair-step region (e.g., 13). Individual stairs (e.g., 70) in the stair-step region comprise one of the conductive tiers and a riser (e.g., 72). The vertical stack comprises insulator material (e.g., 82) in the stair-step region directly above the stairs. A mask (e.g., 91; e.g., comprising photoresist and/or hard-masking material) has been formed directly above the vertical stack. The mask comprises mask openings (e.g., 93) there-through that are individually horizontally-elongated and directly above the insulator material and one of the individual stairs. The mask openings have a first horizontal peripheral shape. In one example and as shown, the first horizontal peripheral shape is rectangular.

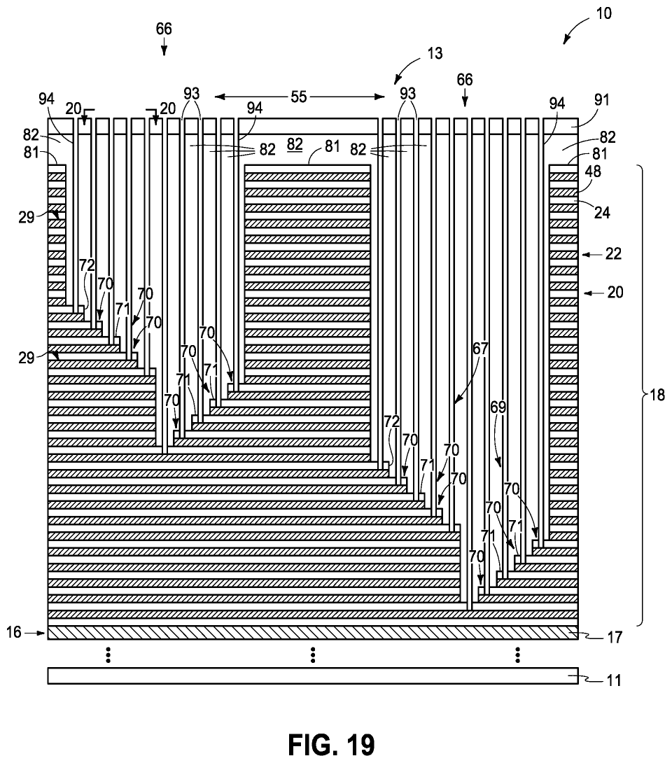

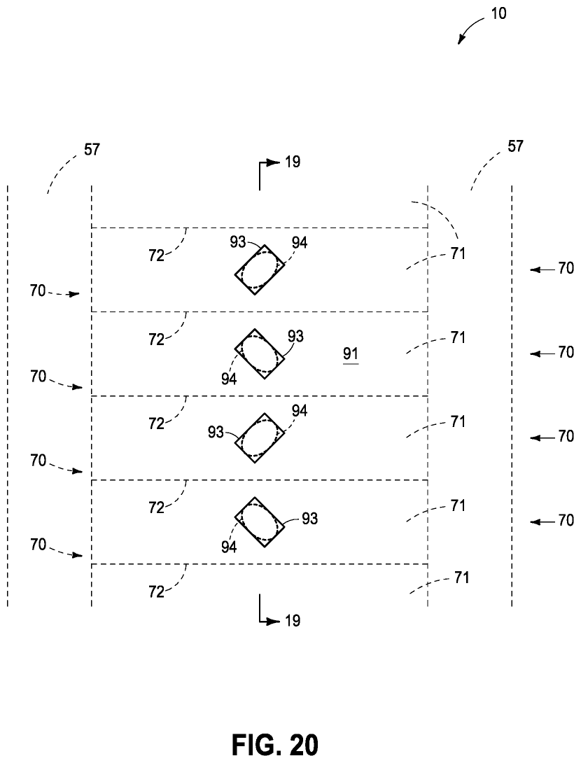

Referring to FIGS. 19 and 20, the insulator material has been etched through the mask openings to form contact openings (e.g., 94) that individually extend through the insulator material to conducting material (e.g., 48) that is in the one conductive tier in the one individual stair. Individual of the contact openings where elevationally at the conductive material are horizontally-elongated and having a second horizontal peripheral shape that is different from the first horizontal peripheral shape, for example and in one embodiment and as shown that is not rectangular.

Conductive material (e.g., 95) is formed in the contact openings to comprise conductive vias (e.g., 80*) that are individually directly against the conductive material in the one individual stair (e.g., FIGS. 7, 9, and 10). The individual contact openings where elevationally at the conductive material and individual of the conductive vias where directly against the conductive material are horizontally-longitudinally-elongated at an angle of 0° to 60° horizontally from the riser of the one individual stair.

The angle of the respective mask opening and the angle of the/its respective contact opening/conductive via may not be the same relative one another, for example with an angular shift thereof occurring due to an artifact of manufacture. Regardless, contact openings for the TAVs (if formed, and not shown in FIGS. 19 and 20) and the contact openings for the conductive vias may be formed in any order relative one another or at the same time.

Any other attribute(s) or aspect(s) as shown and/or described herein with respect to other embodiments may be used.

The above processing(s) or construction(s) may be considered as being relative to an array of components formed as or within a single stack or single deck of such components above or as part of an underlying base substrate (albeit, the single stack/deck may have multiple tiers). Control and/or other peripheral circuitry for operating or accessing such components within an array may also be formed anywhere as part of the finished construction, and in some embodiments may be under the array (e.g., CMOS under-array). Regardless, one or more additional such stack(s)/deck(s) may be provided or fabricated above and/or below that shown in the figures or described above. Further, the array(s) of components may be the same or different relative one another in different stacks/decks and different stacks/decks may be of the same thickness or of different thicknesses relative one another. Intervening structure may be provided between immediately-vertically-adjacent stacks/decks (e.g., additional circuitry and/or dielectric layers). Also, different stacks/decks may be electrically coupled relative one another. The multiple stacks/decks may be fabricated separately and sequentially (e.g., one atop another), or two or more stacks/decks may be fabricated at essentially the same time.

The assemblies and structures discussed above may be used in integrated circuits/circuitry and may be incorporated into electronic systems. Such electronic systems may be used in, for example, memory modules, device drivers, power modules, communication modems, processor modules, and application-specific modules, and may include multilayer, multichip modules. The electronic systems may be any of a broad range of systems, such as, for example, cameras, wireless devices, displays, chip sets, set top boxes, games, lighting, vehicles, clocks, televisions, cell phones, personal computers, automobiles, industrial control systems, aircraft, etc.

In this document unless otherwise indicated, “elevational”, “higher”, “upper”, “lower”, “top”, “atop”, “bottom”, “above”, “below”, “under”, “beneath”, “up”, and “down” are generally with reference to the vertical direction. “Horizontal” refers to a general direction (i.e., within 10 degrees) along a primary substrate surface and may be relative to which the substrate is processed during fabrication, and vertical is a direction generally orthogonal thereto. Reference to “exactly horizontal” is the direction along the primary substrate surface (i.e., no degrees there-from) and may be relative to which the substrate is processed during fabrication. Further, “vertical” and “horizontal” as used herein are generally perpendicular directions relative one another and independent of orientation of the substrate in three-dimensional space. Additionally, “elevationally-extending” and “extend(ing) elevationally” refer to a direction that is angled away by at least 45° from exactly horizontal. Further, “extend(ing) elevationally”, “elevationally-extending”, “extend(ing) horizontally”, “horizontally-extending” and the like with respect to a field effect transistor are with reference to orientation of the transistor's channel length along which current flows in operation between the source/drain regions. For bipolar junction transistors, “extend(ing) elevationally” “elevationally-extending”, “extend(ing) horizontally”, “horizontally-extending” and the like, are with reference to orientation of the base length along which current flows in operation between the emitter and collector. In some embodiments, any component, feature, and/or region that extends elevationally extends vertically or within 10° of vertical.

Further, “directly above”, “directly below”, and “directly under” require at least some lateral overlap (i.e., horizontally) of two stated regions/materials/components relative one another. Also, use of “above” not preceded by “directly” only requires that some portion of the stated region/material/component that is above the other be elevationally outward of the other (i.e., independent of whether there is any lateral overlap of the two stated regions/materials/components). Analogously, use of “below” and “under” not preceded by “directly” only requires that some portion of the stated region/material/component that is below/under the other be elevationally inward of the other (i.e., independent of whether there is any lateral overlap of the two stated regions/materials/components).

Any of the materials, regions, and structures described herein may be homogenous or non-homogenous, and regardless may be continuous or discontinuous over any material which such overlie. Where one or more example composition(s) is/are provided for any material, that material may comprise, consist essentially of, or consist of such one or more composition(s). Further, unless otherwise stated, each material may be formed using any suitable existing or future-developed technique, with atomic layer deposition, chemical vapor deposition, physical vapor deposition, epitaxial growth, diffusion doping, and ion implanting being examples.

Additionally, “thickness” by itself (no preceding directional adjective) is defined as the mean straight-line distance through a given material or region perpendicularly from a closest surface of an immediately-adjacent material of different composition or of an immediately-adjacent region. Additionally, the various materials or regions described herein may be of substantially constant thickness or of variable thicknesses. If of variable thickness, thickness refers to average thickness unless otherwise indicated, and such material or region will have some minimum thickness and some maximum thickness due to the thickness being variable. As used herein, “different composition” only requires those portions of two stated materials or regions that may be directly against one another to be chemically and/or physically different, for example if such materials or regions are not homogenous. If the two stated materials or regions are not directly against one another, “different composition” only requires that those portions of the two stated materials or regions that are closest to one another be chemically and/or physically different if such materials or regions are not homogenous. In this document, a material, region, or structure is “directly against” another when there is at least some physical touching contact of the stated materials, regions, or structures relative one another. In contrast, “over”, “on”, “adjacent”, “along”, and “against” not preceded by “directly” encompass “directly against” as well as construction where intervening material(s), region(s), or structure(s) result(s) in no physical touching contact of the stated materials, regions, or structures relative one another.

Herein, regions-materials-components are “electrically coupled” relative one another if in normal operation electric current is capable of continuously flowing from one to the other and does so predominately by movement of subatomic positive and/or negative charges when such are sufficiently generated. Another electronic component may be between and electrically coupled to the regions-materials-components. In contrast, when regions-materials-components are referred to as being “directly electrically coupled”, no intervening electronic component (e.g., no diode, transistor, resistor, transducer, switch, fuse, etc.) is between the directly electrically coupled regions-materials-components.

Any use of “row” and “column” in this document is for convenience in distinguishing one series or orientation of features from another series or orientation of features and along which components have been or may be formed. “Row” and “column” are used synonymously with respect to any series of regions, components, and/or features independent of function. Regardless, the rows may be straight and/or curved and/or parallel and/or not parallel relative one another, as may be the columns. Further, the rows and columns may intersect relative one another at 90° or at one or more other angles (i.e., other than the straight angle).

The composition of any of the conductive/conductor/conducting materials herein may be metal material and/or conductively-doped semiconductive/semiconductor/semiconducting material. “Metal material” is any one or combination of an elemental metal, any mixture or alloy of two or more elemental metals, and any one or more conductive metal compound(s).

Herein, any use of “selective” as to etch, etching, removing, removal, depositing, forming, and/or formation is such an act of one stated material relative to another stated material(s) so acted upon at a rate of at least 2:1 by volume. Further, any use of selectively depositing, selectively growing, or selectively forming is depositing, growing, or forming one material relative to another stated material or materials at a rate of at least 2:1 by volume for at least the first 75 Angstroms of depositing, growing, or forming.

Unless otherwise indicated, use of “or” herein encompasses either and both.

### CONCLUSION

In some embodiments, memory circuitry comprising strings of memory cells comprising laterally-spaced memory blocks individually comprise a vertical stack comprising alternating insulative tiers and conductive tiers. Channel-material strings of memory cells extend through the insulative tiers and the conductive tiers in a memory-array region. The insulative tiers and the conductive tiers of the laterally-spaced memory blocks extend from the memory-array region into a stair-step region. Individual stairs in the stair-step region comprise one of the conductive tiers and a riser. Conductive vias are individually directly against conducting material that is in the one conductive tier in one of the individual stairs. Individual of the conductive vias where directly against the conducting material are horizontally-longitudinally-elongated at an angle of 0° to 60° horizontally from the riser of the one individual stair.

In some embodiments, memory circuitry comprising strings of memory cells comprising laterally-spaced memory blocks individually comprise a vertical stack comprising alternating insulative tiers and conductive tiers. Channel-material strings of memory cells extend through the insulative tiers and the conductive tiers in a memory-array region. The insulative tiers and the conductive tiers of the laterally-spaced memory blocks extend from the memory-array region into a stair-step region. Individual stairs in the stair-step region comprise one of the conductive tiers, a tread, and a riser. Multiple through-array-vias extend through individual of the risers and through the treads of immediately-adjacent of the stairs. Conductive vias are individually directly against conducting material that is in the one conductive tier in one of the individual stairs. Individual of the conductive vias where directly against the conducting material are horizontally-longitudinally-elongated at an angle of 0° to 60° horizontally from the riser of the one individual stair.

In some embodiments, integrated circuitry comprises a three-dimensional (3D) array region individually comprising tiers of electronic components. The 3D array region comprising a vertical stack comprises alternating insulative tiers and conductive tiers. The insulative tiers and the conductive tiers extend from the 3D array region into a stair-step region. Individual stairs in the stair-step region comprise one of the conductive tiers and a riser. Conductive vias are individually directly against conducting material that is in the one conductive tier in one of the individual stairs. Individual of the conductive vias where directly against the conducting material are horizontally-longitudinally-elongated at an angle of 0° to 60° horizontally from the riser of the one individual stair.

In some embodiments, a method of forming integrated circuitry comprises forming a vertical stack comprising alternating insulative tiers and conductive tiers that will individually comprise tiers of electronic components in a three-dimensional (3D) array region in a finished-circuitry construction. The insulative tiers and the conductive tiers extend from the 3D array region into a stair-step region. Individual stairs in the stair-step region comprise one of the conductive tiers and a riser. The vertical stack comprises insulator material in the stair-step region directly above the stairs. A mask is formed directly above the vertical stack. The mask comprises mask openings there-through that are individually horizontally-elongated and directly above the insulator material and one of the individual stairs. The mask openings have a first horizontal peripheral shape. The insulator material is etched through the mask openings to form contact openings that individually extend through the insulator material to conducting material that is in the one conductive tier in the one individual stair. Individual of the contact openings where elevationally at the conducting material are horizontally-elongated and have a second horizontal peripheral shape that is different from the first horizontal peripheral shape. Conducting material is formed in the contact openings to comprise conductive vias that are individually directly against the conducting material in the one individual stair. The individual contact openings where elevationally at the conducting material and individual of the conductive vias where directly against the conducting material are horizontally-longitudinally-elongated at an angle of 0° to 60° horizontally from the riser of the one individual stair.

In compliance with the statute, the subject matter disclosed herein has been described in language more or less specific as to structural and methodical features. It is to be understood, however, that the claims are not limited to the specific features shown and described, since the means herein disclosed comprise example embodiments. The claims are thus to be afforded full scope as literally worded, and to be appropriately interpreted in accordance with the doctrine of equivalents.

1. Memory circuitry comprising strings of memory cells, comprising:
laterally-spaced memory blocks individually comprising a vertical stack comprising alternating insulative tiers and conductive tiers, channel-material strings of memory cells extending through the insulative tiers and the conductive tiers in a memory-array region;
the insulative tiers and the conductive tiers of the laterally-spaced memory blocks extending from the memory-array region into a stair-step region, individual stairs in the stair-step region comprising one of the conductive tiers and a riser; and
conductive vias that are individually directly against conducting material that is in the one conductive tier in one of the individual stairs, individual of the conductive vias where directly against the conducting material being horizontally-longitudinally-elongated at an angle of 0° to 60° horizontally from the riser of the one individual stair.

2. The memory circuitry of claim 1 wherein the angle is greater than 0° horizontally from the riser of the one individual stair.

3. The memory circuitry of claim 2 wherein the angle is no more than 45° horizontally from the riser of the one individual stair.

4. The memory circuitry of claim 3 wherein the angle is no more than 30° horizontally from the riser of the one individual stair.

5. The memory circuitry of claim 4 wherein the angle is no more than 25° horizontally from the riser of the one individual stair.

6. The memory circuitry of claim 5 wherein the angle is no more than 15° horizontally from the riser of the one individual stair.

7. The memory circuitry of claim 6 wherein the angle is no more than 10° horizontally from the riser of the one individual stair.

8. The memory circuitry of claim 1 wherein the angle is 0°, the individual conductive vias thereby being parallel the riser of the one individual stair.

9. The memory circuitry of claim 1 wherein the individual conductive vias are horizontally-longitudinally-elongated along a maximum-length major axis where directly against the conducting material, the individual conductive vias having a maximum-length minor axis where directly against the conducting material that is orthogonal to the maximum-length major axis, the length of the maximum-length major axis being at least 105% of the length of the maximum-length minor axis.

10. The memory circuitry of claim 9 wherein the length of the maximum-length major axis is no more than 175% of the length of the maximum-length minor axis.

11. The memory circuitry of claim 9 wherein the length of the maximum-length major axis is 110% to 120% of the length of the maximum-length minor axis.

12. The memory circuitry of claim 9 wherein the maximum-length minor axis bisects the maximum-length major axis.

13. The memory circuitry of claim 9 wherein the maximum-length major axis bisects the maximum-length minor axis.

14. The memory circuitry of claim 1 wherein the angle is greater than 0° horizontally-clockwise from the riser of the one individual stair.

15. The memory circuitry of claim 14 wherein the angle is no more than 45° horizontally-clockwise from the riser of the one individual stair.

16. The memory circuitry of claim 15 wherein the angle is no more than 15° horizontally-clockwise from the riser of the one individual stair.

17. The memory circuitry of claim 1 wherein the angle is greater than 0° horizontally-counterclockwise from the riser of the one individual stair.

18. The memory circuitry of claim 17 wherein the angle is no more than 45° horizontally-counterclockwise from the riser of the one individual stair.

19. The memory circuitry of claim 18 wherein the angle is no more than 15° horizontally-counterclockwise from the riser of the one individual stair.

20. The memory circuitry of claim 1 wherein for some of the individual conductive vias the angle is greater than 0° horizontally-clockwise from the riser of the one individual stair and for another some of the individual conductive vias the angle is greater than 0° horizontally-counterclockwise from the riser of the one individual stair.

21. The memory circuitry of claim 20 wherein the angle for the some and the angle for the another some is no more than 45° horizontally from the riser of the one individual stair.

22. The memory circuitry of claim 21 wherein the angle for the some and the angle for the another some is no more than 15° horizontally from the riser of the one individual stair.

23. The memory circuitry of claim 1 comprising through-array-vias individually extending through individual of the individual stairs.

24. Memory circuitry comprising strings of memory cells, comprising:
laterally-spaced memory blocks individually comprising a vertical stack comprising alternating insulative tiers and conductive tiers, channel-material strings of memory cells extending through the insulative tiers and the conductive tiers in a memory-array region;
the insulative tiers and the conductive tiers of the laterally-spaced memory blocks extending from the memory-array region into a stair-step region, individual stairs in the stair-step region comprising one of the conductive tiers, a tread, and a riser;
multiple through-array-vias extending through individual of the risers and through the treads of immediately-adjacent of the stairs; and
conductive vias that are individually directly against conducting material that is in the one conductive tier in one of the individual stairs, individual of the conductive vias where directly against the conducting material being horizontally-longitudinally-elongated at an angle of 0° to 60° horizontally from the riser of the one individual stair.

25-32. (canceled)

33. Integrated circuitry comprising:
a three-dimensional (3D) array region individually comprising tiers of electronic components, the 3D array region comprising a vertical stack comprising alternating insulative tiers and conductive tiers, the insulative tiers and the conductive tiers extending from the 3D array region into a stair-step region, individual stairs in the stair-step region comprising one of the conductive tiers and a riser; and
conductive vias that are individually directly against conducting material that is in the one conductive tier in one of the individual stairs, individual of the conductive vias where directly against the conducting material being horizontally-longitudinally-elongated at an angle of 0° to 60° horizontally from the riser of the one individual stair.

34. A method of forming integrated circuitry, comprising:
forming a vertical stack comprising alternating insulative tiers and conductive tiers that will individually comprise tiers of electronic components in a three-dimensional (3D) array region in a finished-circuitry construction, the insulative tiers and the conductive tiers extending from the 3D array region into a stair-step region, individual stairs in the stair-step region comprising one of the conductive tiers and a riser, the vertical stack comprising insulator material in the stair-step region directly above the stairs;
forming a mask directly above the vertical stack, the mask comprising mask openings there-through that are individually horizontally-elongated and directly above the insulator material and one of the individual stairs, the mask openings having a first horizontal peripheral shape;
etching the insulator material through the mask openings to form contact openings that individually extend through the insulator material to conducting material that is in the one conductive tier in the one individual stair, individual of the contact openings where elevationally at the conducting material being horizontally-elongated and having a second horizontal peripheral shape that is different from the first horizontal peripheral shape; and
forming conductive material in the contact openings to comprise conductive vias that are individually directly against the conducting material in the one individual stair, the individual contact openings where elevationally at the conducting material and individual of the conductive vias where directly against the conducting material being horizontally-longitudinally-elongated at an angle of 0° to 60° horizontally from the riser of the one individual stair.

35-44. (canceled)
